(19) United States
(12) Patent Application Publication
(10) Pub. No.: US 2006/0214244 A1
(43) Pub. Date: Sep. 28, 2006

(54) Semiconductor device and method for fabricating the same

(75) Inventor: Hiroshi Minakata, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/198,166

(22) Filed: Aug. 8, 2005

(30) Foreign Application Priority Data
Mar. 28, 2005 (JP) 2005-092350

(51) Int. Cl. H01L 29/78; H01L 21/4763

(52) U.S. Cl. 257/410; 438/591; 438/711

(57) ABSTRACT

In the method for fabricating a semiconductor device, a polysilicon film is patterned to form a gate electrode 16, and a high dielectric constant insulating film 14 on a silicon substrate 10 and a device isolation film 12 on both sides of the gate electrode 16 is removed by dry etching using plasmas of a mixed gas of a base protection gas which combines with silicon to form a protection layer for protecting the silicon substrate 10 and the device isolation film 12, and an etching gas for etching the high dielectric constant insulating film 14.

### CROSS-REFERENCE TO RELATED APPLICATIONS

This application is based upon and claims priority of Japanese Patent Application No. 2005-092350, filed on Mar. 28, 2005, the contents being incorporated herein by reference.

### BACKGROUND OF THE INVENTION

The present invention relates to a semiconductor device and a method for fabricating the same, more specifically, a semiconductor device including a MIS transistor having a gate insulating film formed of a high dielectric constant insulating film and a method for fabricating the same.

As the MIS transistor is increasingly micronized with the higher integration of semiconductor devices, the gate insulating film is increasingly thinned. Conventionally, silicon oxide film-group insulating films, such as silicon oxide film, silicon oxynitride film or others have been used as a gate insulating film. However, when a silicon oxide film-group insulating film is used as a gate insulating film, the gate leak current due to the tunnel effect is increased as the gate insulating film is increasingly thinned. The silicon oxide film-group insulating film is limited in being thinned.

Recently, as insulating films which can suppress the gate leak current and ensure sufficient dielectric strength voltage in place of the silicon oxide film-group insulating film, insulating films of high dielectric constant materials, such as alumina (Al₂O₃), zirconia (ZrO₂), hafnia (HfO₂), tantalum oxide (Ta₂O₅), etc. are noted. Among them, HfO₂ film, the dielectric constant of which is high and which is thermally relatively stable, is found prospective as a gate insulating film. The use of an insulating film of a higher dielectric constant than the silicon oxide film-group insulating film as a gate insulating film allows the gate insulating film to have a large physical film thickness for an equivalent MIS capacitance. Accordingly, such high dielectric constant insulating film is used as the gate insulating film, whereby the dielectric strength voltage can be improved while equivalent transistor characteristics are realized.

The above-described high dielectric constant insulating film is formed of a material which is not used in the conventional LSI process. For this reason, that of the high dielectric constant insulating film, which is unnecessary after the gate electrode has been patterned, must be removed.

As means for removing the high dielectric constant insulating film, wet processing with solutions and dry processing with gases are considered. As a processing for removing the high dielectric constant insulating film by the dry processing, the process in which halogen plasmas are used to pattern the gate electrodes, etc. while removing the unnecessary part of the high dielectric constant insulating film is disclosed (refer to Japanese published unexamined patent application No. 2004-158487 and Japanese published unexamined patent application No. 2002-75972).

However, in removing the high dielectric constant insulating film by the wet processing, it is often difficult to completely remove the high dielectric constant insulating film. When the processing period of time is increased, there is a risk that even the high dielectric constant insulating film below the gate electrode may be corroded.

On the other hand, in removing the high dielectric constant insulating film by the conventional dry processing, the silicon substrate in the source/drain regions, and lower layers below the high dielectric constant insulating film, such as the device isolation film, etc. are often damaged.

### SUMMARY OF THE INVENTION

An object of the present invention is to provide a semiconductor device which permits the high dielectric constant insulating film to be used as the gate insulating film without deteriorating the transistor characteristics, and a method for fabricating the same.

According to one aspect of the present invention, there is provided a method for fabricating a semiconductor device comprising the steps of: forming a high dielectric constant insulating film on a semiconductor substrate containing silicon; forming a conducting film on the high dielectric constant insulating film; patterning the conducting film to form a gate electrode; removing the high dielectric constant insulating film on the semiconductor substrate on both sides of the gate electrode by dry etching using plasmas of a mixed gas of a first gas which combines with silicon to form a protection layer for protecting the semiconductor substrate and a second gas for etching the high dielectric constant insulating film.

According to another aspect of the present invention, there is provided a semiconductor device comprising: a gate insulating film formed over a semiconductor substrate and formed of a high dielectric constant insulating film; a gate electrode formed on the gate insulating film; a sidewall insulating film formed on a side wall of the gate electrode; and source/drain regions formed in the semiconductor substrate on both sides of the gate electrode, a step between a surface of the semiconductor substrate immediately below the gate insulating film and a surface of the semiconductor substrate immediately below the sidewall insulating film being below 3 nm including 3 nm.

According to the present invention, the high dielectric insulating film is removed by dry etching using plasmas of the mixed gas containing the first gas which combines with silicon of the semiconductor substrate containing silicon to form the protection layer for protecting the semiconductor substrate and the second gas for etching the high dielectric constant insulating film, whereby the high dielectric insulating film can be removed with a high selectivity ratio with respect to the base semiconductor substrate. Thus, the high dielectric insulating film can be used as the gate insulating film without deteriorating the transistor characteristics.

### BRIEF DESCRIPTION OF THE DRAWINGS

FIG. 1 is a sectional view of the semiconductor device according to one embodiment of the present invention, which illustrates a structure thereof.

FIGS. 2A-2C are sectional views of the semiconductor device according to the embodiment of the present invention in the steps of the method for fabricating the same, which illustrate the method (Part 1).

FIGS. 3A-3C are sectional views of the semiconductor device according to the embodiment of the present invention in the steps of the method for fabricating the same, which illustrate the method (Part 2).

FIG. 4 is a sectional view of the plasma etching apparatus used in removing the high dielectric constant insulating film in the method for fabricating the semiconductor device according to the embodiment of the present invention, which illustrates the structure of the plasma etching apparatus.

FIG. 5 is a graph of relationships between the flow rate ratio between Cl₂ and BCl₃ of the mixed gas used in etching the high dielectric constant insulating film, and the etching rate (Part 1).

FIG. 6 is a graph of relationships between the flow rate ratio between Cl₂ and BCl₃ of the mixed gas used in etching the high dielectric constant insulating film, and the etching rate (Part 2).

FIGS. 7A-7C are sectional views of the semiconductor device according to the embodiment of the present invention in the steps of the method for fabricating the same, which illustrate the method (Part 3).

### DETAILED DESCRIPTION OF THE INVENTION

### One Embodiment

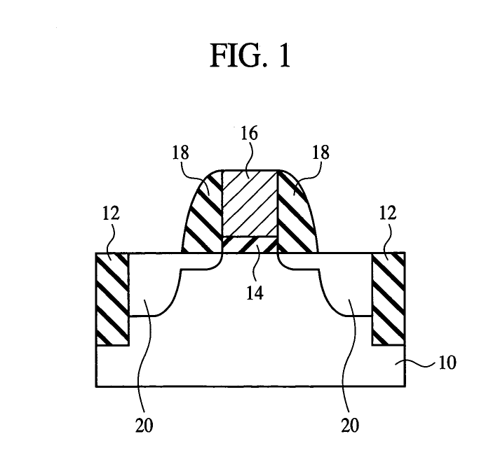

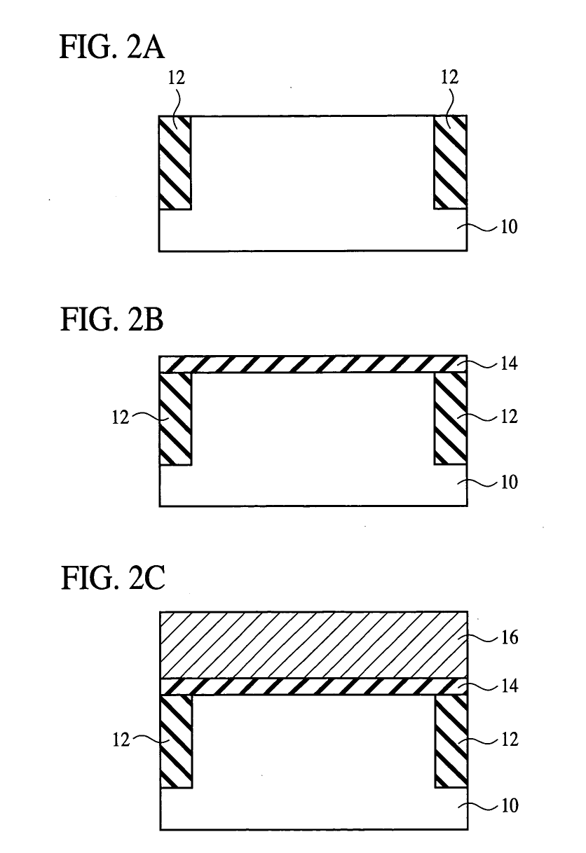

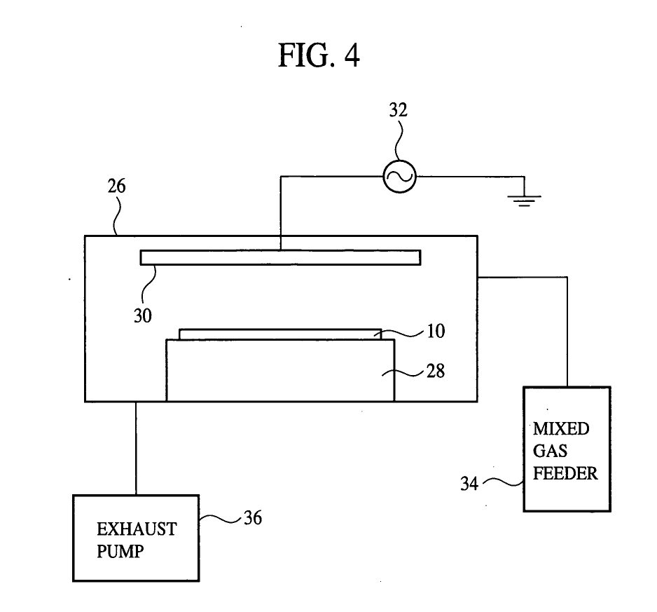

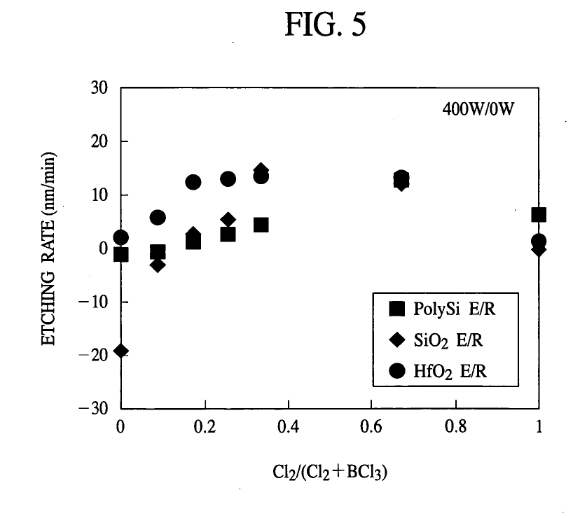

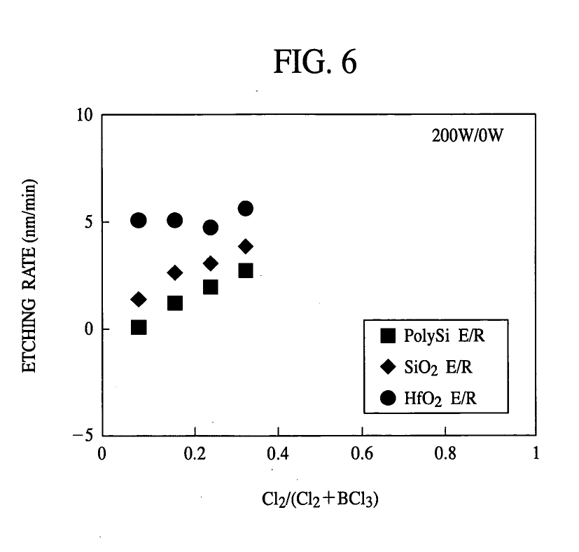

The semiconductor device and the method for fabricating the same according to one embodiment of the present invention will be explained with reference to FIGS. 1 to 7A-7C. FIG. 1 is a sectional view of the semiconductor device according to the present embodiment, which illustrates a structure thereof. FIGS. 2A-2C, 3A-3C and 7A-7C are sectional views of the semiconductor device according to the present embodiment in the steps of the method for fabricating the same, which illustrate the method. FIG. 4 is a sectional view of the plasma etching apparatus used in etching the high dielectric constant insulating film in the method for fabricating the semiconductor device according to the present embodiment, which illustrates the structure of the plasma etching apparatus. FIGS. 5 and 6 are graphs of the relationships between the flow rate ratio between Cl₂ and BCl₃ of the mixed gas used in etching the high dielectric constant insulating film, and the etching rate.

First, the structure of the semiconductor device according to the present embodiment will be explained with reference to FIG. 1.

A device isolation film 12 of a silicon oxide film is formed in the primary surface of a silicon substrate 10. The device isolation film 12 defines a device region in the primary surface of the silicon substrate 10.

On the silicon substrate 10 with the device region defined, a game insulating film 14 of a high dielectric constant insulating film is formed. The gate insulating film 14 is formed of, e.g., hafnia (HfO₂). A gate electrode 16 of a polysilicon film is formed on the gate insulating film 14. A sidewall insulating film 18 is formed on the side wall of the gate electrode 16.

In the silicon substrate 10 on both sides of the gate electrode 16, source/drain regions 20 of the extension source/drain structure are formed.

The height of the surface of the silicon substrate 10 immediately below the sidewall insulating film 18, where the extension regions of the source/drain regions 20 are formed is substantially the same as or a little smaller than the height of the silicon substrate 10 immediately below the gate insulating film 14, which is to be the channel region. The step between the surface of the silicon substrate 10 immediately below the gate insulating film 14, which is to be the channel region and the surface of the silicon substrate immediately below the sidewall insulating film 18, where the extension regions of the source/drain regions 20 are formed is as small as, e.g., below 3 nm including 3 nm.

Thus, a MIS transistor including the gate electrode 16 and the source/drain regions 20 formed on the silicon substrate 10 and using a high dielectric constant insulating film as the gate insulating film 14 is constituted.

The semiconductor device according to the present embodiment is characterized in that, in a MIS transistor using a high dielectric constant insulating film as the gate insulating film 14, the step between the surface of the silicon substrate 10 immediately below the gate insulating film 14 and the surface of the silicon substrate 10 immediately below the sidewall insulating film 18 is as small as, e.g., 3 nm including 3 nm.

As will described later, in the method for fabricating the semiconductor device according to the present embodiment, after the gate electrode 16 has been patterned, the unnecessary part of the high dielectric constant insulating film used as the gate insulating film 14 is removed with a high selectivity ratio with respect to the silicon substrate 10 and the device isolation film 12 formed of a silicon oxide film by dry etching using plasmas of a prescribed mixed gas.

Accordingly, in the semiconductor device according to the present embodiment, the surface of the silicon substrate 10 in the device region has a very small step of, e.g., below 3 nm including 3 nm between the surface of the silicon substrate 10 immediately below the gate insulating film 14 and the surface of the silicon substrate 10 immediately below the sidewall insulating film 18. Thus, a MIS transistor using a high dielectric constant insulating film as the gate insulating film is formed without deterioration of the transistor characteristics.

Next, the method for fabricating the semiconductor device according to the present embodiment will be explained with reference to FIGS. 2A-2C to 7A-7C.

First, a device isolation film 12 of silicon oxide film is formed on a silicon substrate 10 by, e.g., STI (Silicon Trench Isolation) method (see FIG. 2A).

Next, the silicon substrate 10 with the device isolation film 12 formed on is cleaned by chemical liquid cleaning using, e.g., RCA cleaning or others.

Then, on the entire surface of the silicon substrate 10 with the device isolation film 12 formed on, a high dielectric constant insulating film 14 to be a gate insulating film is deposited by, e.g., MOCVD (Metal Organic Chemical Vapor Deposition) method (see FIG. 2B). The high dielectric constant insulating film 14 is, e.g., an about 3.0 nm-thickness HfO₂ film. The high dielectric film 14 may be deposited by ALD (Atomic Layer Deposition) method.

Next, thermal processing is performed in a nitrogen ambient atmosphere or a nitrogen and oxygen mixed ambient atmosphere at, e.g., 600-1100° C. for 0-30 seconds.

Next, on the high dielectric constant insulating film 14, a polysilicon film 16 of, e.g., a 90 nm-thickness is deposited by, e.g., CVD (Chemical Vapor Deposition) method (see FIG. 2C).

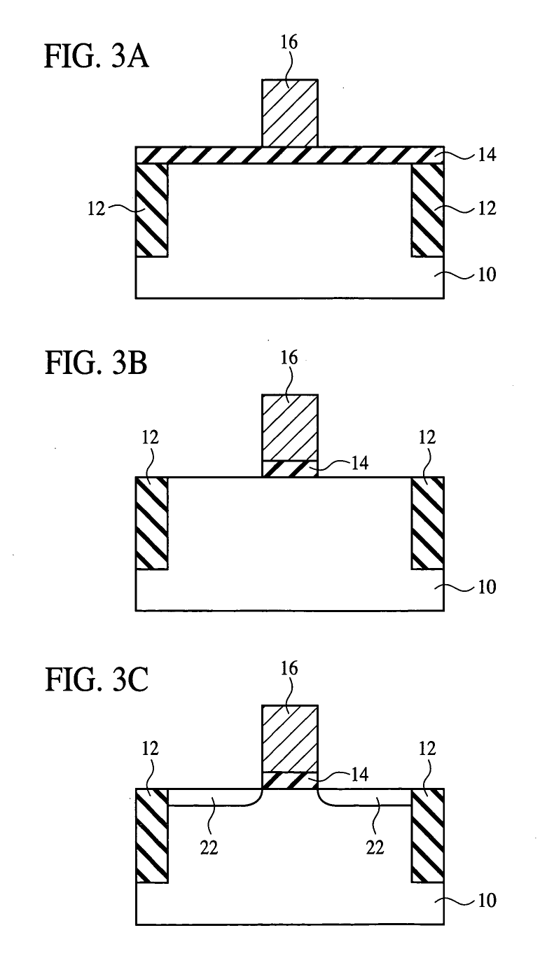

Then, the polysilicon film 16 is patterned by photolithography and dry etching to form a gate electrode 16 of the polsysilicon film (see FIG. 3A).

Next, the high dielectric constant insulating film 14 on the silicon substrate 10 on both sides of the gate electrode 16 and on the device isolation film 12 is removed by dry etching using plasmas of a prescribed mixed gas with the gate electrode 16 as the mask (see FIG. 3B).

In the method for fabricating the semiconductor device according to the present embodiment, the high dielectric constant insulating film 14 is removed by dry etching using plasmas of the mixed gas of a base protection gas which combines with the Si atoms of the silicon substrate 10 and the Si atoms of the device isolation film 12 of the silicon oxide film to form a protection layer, and an etching gas for etching the high dielectric constant insulating film 14. The removal of the high dielectric constant insulating film 14 by the dry etching using the plasmas of the mixed gas will be detailed.

The gases forming the mixed gas used in dry etching the high dielectric constant insulating film 14 of HfO₂ film are specifically as follows.

The base protection gas which combines with the Si atoms of the silicon substrate 10 and the Si atoms of the device isolation film 12 of the silicon oxide film to form a protection layer is, e.g., boron trichloride (BCl₃). The B atoms of the BCl₃ combine with the Si atoms of the silicon substrate 10 and with the Si atoms of the device isolation film 12 of silicon oxide film to form the protection layer on the surface of the silicon substrate 10 and the surface of the device isolation film 12. The protection film protects the silicon substrate 10 and the device isolation film 12, which are the base of the high dielectric constant insulating film 12 to be etched, from the etching. The base protection gas never reacts with the high dielectric constant insulating film 14 to thereby form the protection layer for the protecting the high dielectric constant insulating film 14 from the etching.

The etching gas for etching the high dielectric constant insulating film 14 of HfO₂ film is, e.g., chlorine (Cl₂).

As a gas forming the mixed gas, in addition to the base protection gas and the etching gas described above, a dilution gas is used. The dilution gas is, e.g., argon (Ar). The dilution gas adjusts the etching rate of the high dielectric constant insulating film 14 and stably generating plasmas. A mixed gas formed of only the based protection gas and the etching gas described above without the dilution gas may be used.

FIG. 4 is a sectional view of one example of the plasma etching apparatus used in removing the high dielectric constant insulating film 14.

As illustrated, a susceptor 28 for the silicon substrate 10 having the unnecessary part of the high dielectric constant insulating film 14 to be removed is disposed in the chamber 26.

An upper electrode 30 is disposed above the silicon substrate 10 in the chamber 26, opposed to the silicon substrate 10. The upper electrode 28 is connected to a radio frequency electric power source 32 for applying radio frequency electric power to the upper electrode 28.

A mixed gas feeder 34 for supplying the above-described mixed gas into the chamber 26 is connected to the chamber 26. The exhaust pump 36 for discharging the gas in the chamber 26 is connected to the chamber 26.

When the high dielectric constant insulating film 14 is dry etched, the mixed gas is fed into the chamber 26 from the mixed gas feeder 24 while the inside of the chamber 26 is exhausted by the exhaust pump 36, whereby the inside of the chamber 26 is kept under a certain pressure. In this state, a radio frequency electric power is applied to the upper electrode 30 by the radio frequency electric power source 32 to thereby generate plasmas of the mixed gas between the silicon substrate 10 and the upper electrode 30. The radio frequency electric power to be applied to the upper electrode 30 is, e.g., 200-400 W. The radio frequency electric power to be applied to the upper electrode 30 is not limited to this range and can be, e.g., 50-1000 W.

At this time, no electric power is applied to the silicon substrate 10. Accordingly, no ion sheath is formed on the surface of the silicon substrate 10 with the high dielectric constant insulating film 14 formed on. Thus, the high dielectric constant insulating film 14 is etched by the remote plasmas. The plasmas are thus generated under a condition which generates no ion sheath on the surface of the high dielectric constant insulating film 14, whereby the silicon substrate 10 below the high dielectric constant insulating film 14 and the device isolation film 12 below the high dielectric constant insulating film 14 can be kept from being damaged.

The plasma etching apparatus used in removing the high dielectric constant insulating film 14 is not limited to the structure illustrated in FIG. 4. For example, a dual frequency plasma etching apparatus further including, in addition to the upper electrode, a lower electrode for applying the radio frequency electric power to the silicon substrate 10 may be used, and in this case, the radio frequency electric power is not applied to the lower electrode but is applied only to the upper electrode, so as to generate plasmas.

In the method for a fabricating the semiconductor device according to the present embodiment, the mixed gas used in the dry etching of the high dielectric constant insulating film 14 has the ratio of the flow rate of the etching gas to the total flow rate of the flow rate of the base protection gas and the flow rate of the etching gas set at above 0.01 including 0.01 and below 0.5 including 0.5.

FIGS. 5 and 6 are graphs of the experimentally given results of the relationships between the ratio of the Cl₂ flow rate of the mixed gas to the total flow rate of the Cl₂ flow rate and the BCl₃ flow rate of the mixed gas (Cl₂/(Cl₂+BCl₃)), and the etching rates of polysilicon film, silicon oxide film and HfO₂ film. The ratio of the Cl₂ flow rate of the mixed gas to the total flow rate of the Cl₂ flow rate and the BCl₃ flow rate (Cl₂/(Cl₂+BCl₃)) is taken on the horizontal axis, and the etching rates of the respective films are taken on the vertical axis.

The etching rate was measured on the respective films formed on silicon wafers. The etching rate of the polysilicon film was measured, based on the assumption that the etching rate of the polysilicon film can be approximated to that of the silicon substrate. The mixed gas used for the etching is the mixed gas of Cl₂, BCl₃ and Ar. The plasma etching apparatus is a dual frequency plasma etching apparatus. In the case shown in FIG. 5, the radio frequency electric power applied to the upper electrode was 400 W, while no radio frequency electric power was applied to the lower electrode. In the case shown in FIG. 6, the radio frequency electric power applied to the upper electrode was 200 W, while no radio frequency electric power was applied to the lower electrode.

As evident in FIGS. 5 and 6, in the range where the ratio of the Cl₂ flow rate to the total flow rate of the Cl₂ flow rate and the BCl₃ flow rate (Cl₂/(Cl₂+BCl₃)) is below 0.5 including 0.5, the etching rate of the HfO₂ film is higher in comparison with the etching rate of the polysilicon film and the etching rate of the silicon oxide film. That is, based on the graphs of FIGS. 5 and 6, it is seen that the ratio of the Cl₂ flow rate to the total flow rate of the Cl₂ flow rate and the BCl₃ flow rate (Cl₂/(Cl₂+BCl₃)) is set at below 0.5 including 0.5, whereby the HfO₂ film can be etched in a high selectivity ratio with respect to both the polysilicon film and the silicon oxide film.

Some etching rate of the HfO₂ film must be obtained. In view of this, it is preferable to set the ratio of the Cl₂ flow rate to the total flow rate of the Cl₂ flow rate and the BCl₃ flow rate at above 0.01 including 0.01.

As described above, in the method for fabricating the semiconductor device according to the present embodiment, the mixed gas used in the dry etching of the high dielectric constant insulating film 14 has the ratio of *the flow rate of the etching gas to the total flow rate of the flow rate of the base protection and the flow rate of the etching gas set at above 0.01 including 0.01 and below 0.5 including 0.5, whereby the unnecessary part of the high dielectric constant insulating film 14 can be etched off in a high selectivity ratio with respect to the silicon substrate 10 and the device isolation film 12 of silicon oxide film.

Resultantly, when the unnecessary part of the high dielectric constant insulating film used as the gate insulating film 14 is removed, the etching of the part of the silicon substrate 10 below the high dielectric constant insulating film 14, where the source/drain regions 20 are to be formed, is suppressed, and the height decrease of the part is suppressed. Furthermore, the etching of the part of the device isolation film 12 of silicon oxide film below the high dielectric constant insulating film 14 is suppressed, and the height decrease of the part is suppressed.

Accordingly, the surface of the silicon substrate 10 in the device region has a very small step of, e.g., below 3 nm between the surface of the silicon substrate 10 immediately below the gate electrode 16, i.e., immediately below the gate insulating film 14 and the surface of the silicon substrate 10 immediately below the sidewall insulating film 18.

Thus, the high dielectric constant insulating film 14 can be used as the gate insulating film without deteriorating the transistor characteristics.

After the unnecessary part of the high dielectric constant insulating film 14 has been removed as described above, a dopant impurity is implanted in the silicon substrate 10 on both sides of the gate electrode 16 by, e.g., ion implantation with the gate electrode 16 as the mask. Thus, shallow impurity diffused regions 22 forming the extension regions of the extension source/drain structure are formed (see FIG. 3C).

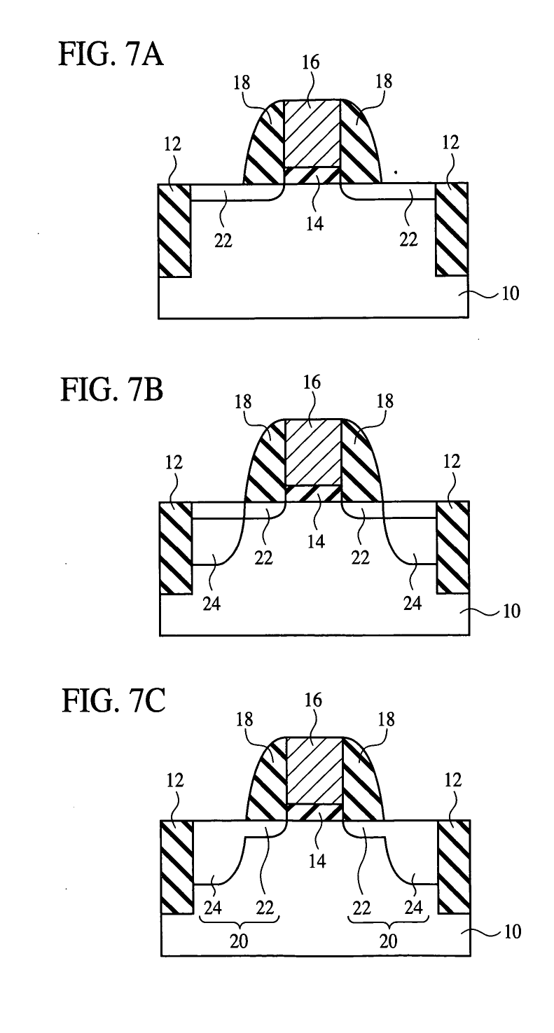

Next, a silicon oxide film of, e.g., a 70 nm-thickness is formed on the entire surface by, e.g., CVD method and is anisotropically etched by, e.g., RIE (Reactive Ion etching) method. Thus, a sidewall insulating film 18 of the silicon oxide film is formed on the side wall of the gate electrode 16 (see FIG. 7A) The sidewall insulating film 18 is formed of silicon oxide film, but the sidewall insulating film 18 is not limited to silicon oxide film. Any other insulating film can be suitably used.

Next, with the gate electrode 16 and the sidewall insulating film 18 as the mask, a dopant impurity is implanted in the silicon substrate 10 on both sides of the gate electrode 16 and the sidewall insulating film 18. Thus, impurity diffused regions 24 forming the deep regions of the source/drain diffused layers are formed (see FIG. 7B).

Then, prescribed thermal processing is performed to activate the dopant impurities implanted in the impurity diffused regions 22, 24. Thus, source/drain regions 20 having the extension regions, i.e., the shallow impurity diffused regions 22, and the deep impurity diffused regions 24 are formed in the silicon substrate 10 on both sides of the gate electrode 16 (see FIG. 7C).

Thus, a MIS transistor using the high dielectric constant insulating film as the gate insulating film 14 is fabricated.

As described above, according to the present embodiment, the unnecessary part of the high dielectric constant insulating film 14 is removed with the plasmas of the mixed gas of the base protection gas which combines with the Si atoms of the silicon substrate 10 and the Si atoms of the device isolation film 12 of silicon oxide film to form the protection layer, and the etching gas for etching the high dielectric constant insulating film 14 which are mixed in a prescribed flow rate ratio, whereby the high dielectric constant insulating film 14 can be etched off in a high selectivity ratio with respect to the base silicon substrate 10 and the device isolation film 12. Thus, the high dielectric constant insulating film 14 can be used as the gate insulating film without deteriorating the transistor characteristics.

### Modified Embodiments

The present invention is not limited to the above-described embodiment and can cover other various modifications.

For example, in the above-described embodiment, the high dielectric constant insulating film used as the gate insulating film 14 is HfO₂ film but is not limited to HfO₂ film. The high dielectric constant insulating film used as the gate insulating film 14 can be a high dielectric film of metal oxide, such as alumina (Al₂O₃) film, zirconia (ZrO₂), hafnia (HfO₂) film, tantalum oxide (Ta₂O₅) film or others. The high dielectric constant insulating film used as the gate insulating film 14 may be a film of an Hf-group compound with silicon or nitrogen added to, such as HfSiO, HfSiON, HfON or others.

In the above-described embodiment, BCl₃ is used as the base protection gas for protecting the silicon substrate 10 and the device isolation film 12 but the base protection gas is not limited to BCl₃. Carbon tetrachloride (CCl₄) or others may be used as the base protection gas.

In the above-described embodiment, Cl₂ is used as the etching gas for etching the high dielectric constant insulating film 14 but the etching gas is not limited to Cl₂. The etching gas may be carbon tetrafluoride (CF₄), sulfur hexafluoride (SF₆), fluorine (F₂), nitrogen trifluoride (NF₃), chlorine trifluoride (ClF₃) or others.

In the above-described embodiment, the dilution gas contained in the mixed gas for etching the high dielectric constant insulating film 14 is Ar but the dilution gas is not limited to Ar. The dilution gas only has to be an inert gas and can be a rare gas, such as helium (He), neon (Ne), krypton (Kr), xenon (Xe) or others, nitrogen (N₂), or others.

In the above-described embodiment, the device isolation film 12 is formed by STI but the method for forming the device isolation film 12 is not limited to STI. The device isolation film 12 may be formed by LOCOS (Local Oxidation of Silicon) or others.

In the above-described embodiment, the high dielectric constant insulating film 14 is formed on the silicon substrate 10 and on the device isolation film 12 of silicon oxide film. However, the present invention is applicable widely in cases where a high dielectric constant insulating film formed on a semiconductor substrate containing silicon and on a device isolation film containing silicon.

What is claimed is:

1. A method for fabricating a semiconductor device comprising the steps of:
forming a high dielectric constant insulating film on a semiconductor substrate containing silicon;
forming a conducting film on the high dielectric constant insulating film;
patterning the conducting film to form a gate electrode;
removing the high dielectric constant insulating film on the semiconductor substrate on both sides of the gate electrode by dry etching using plasmas of a mixed gas of a first gas which combines with silicon to form a protection layer for protecting the semiconductor substrate and a second gas for etching the high dielectric constant insulating film.

2. A method for fabricating a semiconductor device according to claim 1, wherein
in the step of forming the high dielectric constant insulating film, the high dielectric constant insulating film is formed on the semiconductor substrate, and a device isolation film formed on the semiconductor substrate and containing silicon.

3. A method for fabricating a semiconductor device according to claim 1, wherein
a ratio of a flow rate of the second gas to a total flow rate of a flow rate of the first gas and a flow rate of the second gas is above 0.01 including 0.01 and below 0.5 including 0.5.

4. A method for fabricating a semiconductor device according to claim 2, wherein
a ratio of a flow rate of the second gas to a total flow rate of a flow rate of the first gas and a flow rate of the second gas is above 0.01 including 0.01 and below 0.5 including 0.5.

5. A method for fabricating a semiconductor device according to claim 1, wherein
the first gas is boron trichloride or carbon tetrachloride.

6. A method for fabricating a semiconductor device according to claim 2, wherein
the first gas is boron trichloride or carbon tetrachloride.

7. A method for fabricating a semiconductor device according to claim 1, wherein
the second gas is chlorine, carbon tetrafluoride, sulfur hexafluoride, fluorine, nitrogen trifluoride, chlorine trifluoride.

8. A method for fabricating a semiconductor device according to claim 2, wherein
the second gas is chlorine, carbon tetrafluoride, sulfur hexafluoride, fluorine, nitrogen trifluoride, chlorine trifluoride.

9. A method for fabricating a semiconductor device according to claim 1, wherein
the mixed gas further contains a third gas for dilution.

10. A method for fabricating a semiconductor device according to claim 2, wherein
the mixed gas further contains a third gas for dilution.

11. A method for fabricating a semiconductor device according to claim 9, wherein
the third gas is helium, neon, argon, krypton or xenon.

12. A method for fabricating a semiconductor device according to claim 10, wherein
the third gas is helium, neon, argon, krypton or xenon.

13. A method for fabricating a semiconductor device according to claim 1, wherein
in the step of removing the high dielectric constant insulating film, the plasmas of the mixed gas are generated under a condition which forms no ion sheath on a surface of the high dielectric constant insulating film.

14. A method for fabricating a semiconductor device according to claim 2, wherein
in the step of removing the high dielectric constant insulating film, the plasmas of the mixed gas are generated under a condition which forms no ion sheath on a surface of the high dielectric constant insulating film.

15. A method for fabricating a semiconductor device according to claim 13, wherein
in the step of removing the high dielectric constant insulating film, the plasmas of the mixed gas are generated by applying no radio frequency electric power to the semiconductor substrate but applying radio frequency electric power to an upper electrode opposed to the semiconductor substrate.

16. A method for fabricating a semiconductor device according to claim 14, wherein
in the step of removing the high dielectric constant insulating film, the plasmas of the mixed gas are generated by applying no radio frequency electric power to the semiconductor substrate but applying radio frequency electric power to an upper electrode opposed to the semiconductor substrate.

17. A semiconductor device comprising:
a gate insulating film formed over a semiconductor substrate and formed of a high dielectric constant insulating film;
a gate electrode formed on the gate insulating film;
a sidewall insulating film formed on a side wall of the gate electrode; and
source/drain regions formed in the semiconductor substrate on both sides of the gate electrode,
a step between a surface of the semiconductor substrate immediately below the gate insulating film and a surface of the semiconductor substrate immediately below the sidewall insulating film being below 3 nm including 3 nm.

18. A semiconductor device according to claim 17, wherein
the high dielectric constant insulating film is hafnium film, alumina film, zirconia film or tantalum oxide film.
